(19) United States
(12) Patent Application Publication
(10) Pub. No.: US 2007/0247950 A1
(43) Pub. Date: Oct. 25, 2007

(54) Memory device with reduced stand-by mode power consumption

(75) Inventors: Cheng Hung Lee, Hsinchu County (TW); Hung-Jen Liao, Hsin-Chu (TW)

Correspondence Address: Howard Chen, Esq.;Preston Gates & Ellis LLP, Suite 1700, 55 Second Street, San Francisco, CA, 94105, US

(73) Assignee: Taiwan Semiconductor Manufacturing Co., Ltd.

(21) Appl. No.: 11/407,593

(22) Filed: Apr. 20, 2006

(51) Int. Cl. G11C 5/14

(52) U.S. Cl. 365/226

(57) ABSTRACT

The present invention discloses a memory device. In one embodiment of the present invention, the memory device includes at least one memory array having a plurality of memory cells addressed by a plurality of word lines and bit lines. At least one word line decoder is coupled to the word lines for selecting the memory cell for read or write operation. The word line decoder includes at least one last stage driver having at least one PMOS transistor and at least one NMOS transistor, the PMOS transistor having a threshold voltage substantially higher than that of the NMOS transistor, thereby reducing the power consumption of the memory device in the stand-by mode.

### BACKGROUND

The present invention relates generally to an integrated circuit (IC) design, and more particularly to memory device with reduced stand-by mode power consumption.

A memory device typically includes one or more memory cell arrays, a word line decoder, a read/write circuit, and a control circuit. The memory cell array includes a plurality of memory cells located at intersections of rows of word lines and columns of bit lines. The word line decoder selects a word line for reading or writing information from or into one or more memory cells connected to the selected word line. The read/write circuit selects the bit lines for reading or writing data from or into one or more selected memory cells. The control circuit controls the word line decoder and the read/write circuit for selecting one or more particular memory cells in response to inputs received from outside of the memory device.

One of the challenges in designing a memory device, embedded memory or system-on-chip (SoC) is to lower its power consumption. For example, many memory devices are designed to consume less power when they are in the stand-by mode. While this scheme significantly reduces the power consumption for the memory cells, it does not reduce the power consumption for the peripheral circuits, such as the word line decoder, as significantly as it does for the memory cells. As such, it is desired to further reduce the power consumption of the peripheral circuits in order to further reduce the total power consumption of the memory device during the stand-by mode.

### SUMMARY

The present invention discloses a memory device. The memory device can be stand-alone memory such as stand-alone SRAM and stand-alone DRAM, embedded memory such as logic embedded SRAM and logic embedded DRAM or system-on-chip (SoC). In one embodiment of the present invention, the memory device includes at least one memory array having a plurality of memory cells addressed by a plurality of word lines and bit lines. At least one word line decoder is coupled to the word lines for selecting the memory cell for read or write operation. The word line decoder includes at least one last stage driver having at least one PMOS transistor and at least one NMOS transistor, the PMOS transistor having a threshold voltage substantially higher than that of the NMOS transistor, thereby reducing the power consumption of the memory device in the stand-by mode.

The construction and method of operation of the invention, however, together with additional objectives and advantages thereof will be best understood from the following description of specific embodiments when read in connection with the accompanying drawings.

### BRIEF DESCRIPTION OF THE DRAWINGS

FIG. 1 illustrates a block diagram of a memory structure in accordance with one embodiment of the present invention.

FIG. 2 shows an exemplary distribution of power consumption for a memory device during the stand-by mode.

FIG. 3 graphically illustrates the electrical characteristic variations for PMOS transistors with various threshold voltages.

FIG. 4 graphically illustrates the electrical characteristic variations for NMOS transistors with various threshold voltages.

### DESCRIPTION

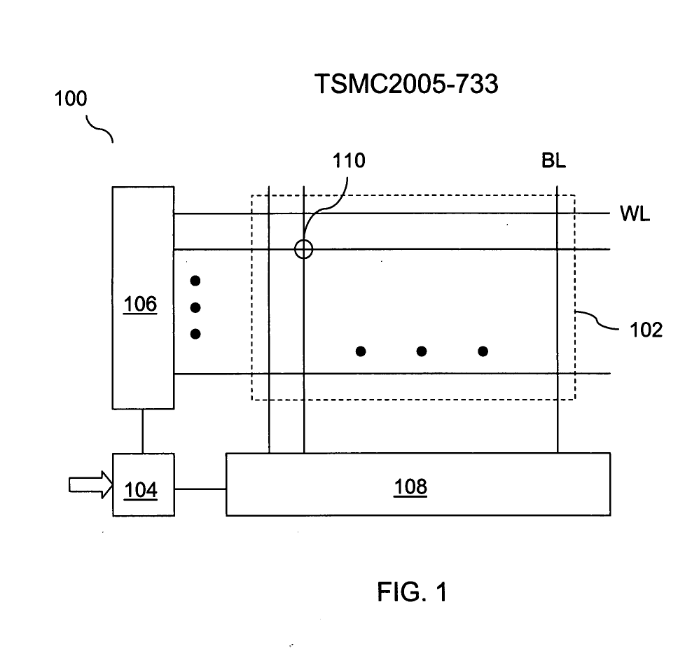

FIG. 1 illustrates a block diagram of a memory structure 100 in accordance with one embodiment of the present invention. In this embodiment, the memory structure 100 is a static random access memory (SRAM) device, such as the six-transistor, eight-transistor, and twelve-transistor SRAM. It is noted that while the application uses the SRAM device as an example for description, the principles of the invention can be applied to other types of memory devices. For example, the memory device can be a dynamic random access memory (DRAM) device comprising a trenched capacitor, stacked capacitor or MiM capacitor. As another example, the memory device can be a non-volatile memory device comprising a stacked gate flash memory, or silicon-oxide-nitride-oxide-silicon (SONOS) flash memory.

The memory structure 100 includes a memory array 102 having a plurality of memory cells 110 located at intersections of rows of word lines (WL) and columns of bit lines (BL). The word lines (WL) are connected to a word line decoder 106 and the bit lines (BL) are connected to a read/write circuit 108. The word line decoder 106 and the read/write circuit 108 are connected to a control circuit 104 that receives an external input. It is noted that while FIG. 1 shows only one memory array 102, one word line decoder 106, one read/write circuit 108, and one control circuit 104, their numbers can vary in real applications.

The word line decoder 106 typically includes a decoding circuit, buffers, and a last stage driver (not shown in this figure). The decoding circuit decodes the address signals. The last stage driver, which is typically constructed by a number of PMOS transistors connected with a number of NMOS transistors, selects the word lines in response to the outputs of the decoding circuit. The read/write circuit 108 typically includes a multiplexer/de-multiplexer (not shown in the figure) for allowing the selected memory cell to be accessed for a read or write operation via the bit line. The read/write circuit 108 also typically includes a sense amplifier (not shown in the figure) for amplifying the voltage output from the selected memory cell.

The function of the word line decoder 106 and the read/write circuit 108 can be understood by describing how they work together to achieve a read operation. During a read operation, the word line decoder 106 selects a word line (WL) for allowing the access to the memory cells connected to the selected word line. The read/write circuit 108 amplifies the voltage on bit lines (BL), representative of the stored value of the selected memory cells, and outputs the amplified voltage to complete the read operation.

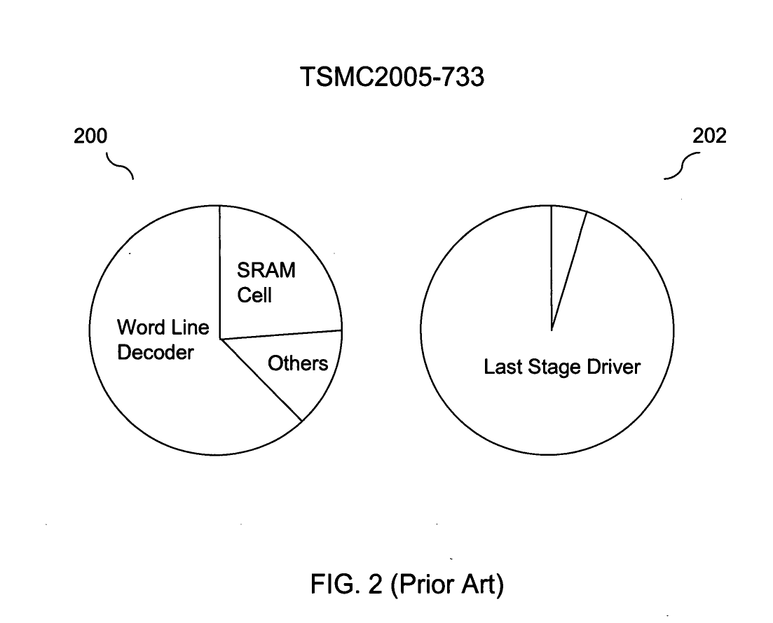

One challenge for designing a memory device is to lower its power consumption, especially when the device is in a stand-by mode. FIG. 2 graphically illustrates the power distribution of a conventional memory device in the stand-by mode. The graph 200 shows that the word line decoder consumes a major part of the power. The graph 202 shows among the power consumed by the word line decoder, more than 90 percent is consumed by the last stage driver of the word line decoder.

The present invention proposes a scheme that modifies the conventional last stage driver of the word line decoder in order to reduce the power consumption of the memory device in the stand-by mode.

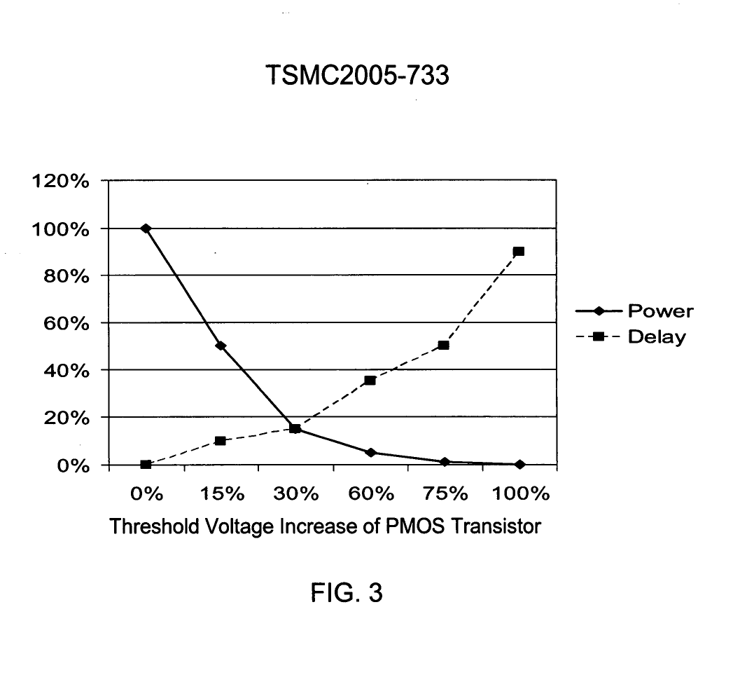

FIG. 3 graphically illustrates the electrical characteristic variations for PMOS transistors with various threshold voltages in accordance with one embodiment of the present invention. As shown in the graph, increasing the threshold voltage of the PMOS transistor within the last stage driver dramatically decreases the power consumption of the last stage driver. However, increasing the threshold voltage of the PMOS transistor of the last stage driver causes the PMOS transistor to delay its switching of states. Thus, it is desired to optimize the threshold voltage of the PMOS transistor in the last stage driver, while avoiding the delay from increasing beyond an acceptable range.

When the threshold voltage of the PMOS transistor is increased by 15%, the stand-by power consumption decreases to about 50% of its original value and the delay increases by about 10%. When the threshold voltage of the PMOS transistor is increased by 30%, the stand-by power consumption decreases to about 15% of its original value and the delay increases by about 15%. When the threshold voltage of the PMOS transistor is increased by 60%, the stand-by power consumption decreases to about 5% of its original value and the delay increases by about 35%. When the threshold voltage of the PMOS transistor is increased by 75%, the stand-by power consumption decreases to about 1% of its original value and the delay increases by about 50%. As such, increasing the threshold voltage of the PMOS transistor of the last stage driver by 15% to 75% results in reduction of stand-by power consumption from 50% to 1% and the delay is maintained within a 50% increase.

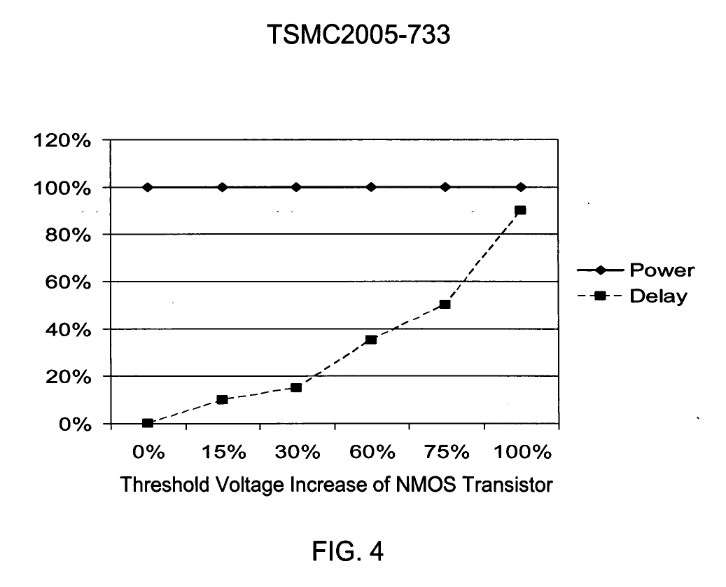

FIG. 4 graphically illustrates the electrical characteristic variations for NMOS transistors with various threshold voltages in accordance with one embodiment of the present invention. As shown in the graph, the stand-by power consumption remains constant as the threshold voltage is increased. The switch delay of the NMOS transistors increases as the threshold voltage is increased. As such, increasing the threshold voltage of the NMOS transistors in the last stage driver cannot reduce the power consumption of the memory device. Moreover, it will increase the switch delay.

The embodiment of the invention proposes to increase the threshold voltage of the PMOS transistors of the last stage driver by 15% to 75% higher than that of the NMOS transistors of the last stage driver, so that the power consumption of the memory device can be significantly reduced. Specifically, it is preferably to reduce the threshold voltage of the PMOS transistors of the last stage by 30% to 60% higher than that of the NMOS transistors in order to optimize the decrease of power consumption and the increase of switch delay. Thus, the power consumption of the memory device can be significantly reduced in the stand-by mode.

There are various ways of increasing the threshold of the PMOS transistor. For example, the gate dielectric of the PMOS transistor can be made thicker than that of the NMOS transistor so that the threshold voltage of the PMOS transistor can be higher than that of the NMOS transistor. As another example, the gate dielectric of the PMOS transistor can be made of materials with higher dielectric constants. In one embodiment, the gate dielectric of the PMOS transistor can be made by a dielectric material with a dielectric constant higher than 20 through an atomic layer chemical vapor deposition (ALCVD) or sputtering process.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. An embedded memory device comprising:
at least one memory array having a plurality of memory cells addressed by a plurality of word lines and bit lines; and
at least one word line decoder coupled to the word lines for selecting the memory cell for read or write operation,
wherein the word line decoder includes at least one last stage driver having at least one PMOS transistor and at least one NMOS transistor, the PMOS transistor having a threshold voltage substantially higher than that of the NMOS transistor.

2. The embedded memory device of claim 1, wherein the threshold voltage of the PMOS transistor is higher than that of the NMOS transistor by approximate 15% to 75%.

3. The embedded memory device of claim 1, wherein the threshold voltage of the PMOS transistor is higher than that of the NMOS transistor by approximate 30% to 60%.

4. The embedded memory device of claim 1 is a six-transistor, eight-transistor, or twelve-transistor SRAM device.

5. The embedded memory device of claim 1 is a DRAM device comprising a trenched capacitor, stacked capacitor or MiM capacitor.

6. The embedded memory device of claim 1 is a non-volatile memory device comprising a stacked gate flash memory, or SONOS flash memory.

7. The embedded memory device of claim 1, wherein the PMOS transistor has a gate dielectric thicker than that of the NMOS transistor.

8. The embedded memory device of claim 1, wherein the PMOS transistor has a gate dielectric whose dielectric constant is high than that of the NMOS transistor.

9. The embedded memory device of claim 8, wherein the gate dielectric of the PMOS transistor has a dielectric constant higher than 20.

10. The embedded memory device of claim 1, wherein increasing the threshold voltage of the PMOS transistor reduces power consumption of the memory device in a stand-by mode.

11. A memory device comprising:
at least one memory array having a plurality of memory cells addressed by a plurality of word lines and bit lines; and
at least one word line decoder coupled to the word lines for selecting the memory cell for read or write operation,
wherein the word line decoder includes at least one last stage driver having at least one PMOS transistor and at least one NMOS transistor, the PMOS transistor having a threshold voltage higher than that of the NMOS transistor by approximate 15% to 75%.

12. The memory device of claim 11, is an SRAM, DRAM or non-volatile memory.

13. The memory device of claim 11, wherein the PMOS transistor has a gate dielectric thicker than that of the NMOS transistor.

14. The memory device of claim 11, wherein the PMOS transistor has a gate dielectric whose dielectric constant is high than that of the NMOS transistor.

15. The memory device of claim 14 wherein the gate dielectric of the PMOS transistor has a dielectric constant higher than 20.

16. The memory device of claim 11 wherein increasing the threshold voltage of the PMOS transistor reduces power consumption of the memory device in a stand-by mode.

17. An embedded memory device comprising:
at least one memory array having a plurality of memory cells addressed by a plurality of word lines and bit lines; and
at least one word line decoder coupled to the word lines for selecting the memory cell for read or write operation,
wherein the word line decoder includes at least one last stage driver having at least one PMOS transistor and at least one NMOS transistor,
wherein the PMOS transistor has a gate dielectric thicker than that of the NMOS transistor, or has a gate dielectric constant higher than that of the NMOS transistor.

18. The embedded memory device of claim 17, wherein the threshold voltage of the PMOS transistor is higher than that of the NMOS transistor by approximate 15% to 75%.

19. The embedded memory device of claim 17 is an SRAM, DRAM or non-volatile memory.

20. The embedded memory device of claim 17, wherein increasing the threshold voltage of the PMOS transistor reduces power consumption of the memory device in a stand-by mode.
